(19) United States
(12) Patent Application Publication
(10) Pub. No.: US 2017/0125069 A1
(43) Pub. Date: May 4, 2017

(54) SEMICONDUCTOR DEVICE INCLUDING MULTIPLE PLANES

(71) Applicant: SK hynix Inc., Gyeonggi-do (KR)

(72) Inventor: Hyun Su YOON, Gyeonggi-do (KR)

(21) Appl. No.: 15/093,973

(22) Filed: Apr. 8, 2016

(30) Foreign Application Priority Data
Nov. 4, 2015 (KR) 10-2015-0154518

(51) Int. Cl. G11C 5/14; G11C 7/00

(52) U.S. Cl. CPC G11C 5/147; G11C 7/00

(57) ABSTRACT

Provided herein is a semiconductor device including first and second regulators suitable for respectively generating first and second regulating voltages; first and second planes; a first peripheral circuit suitable for operating the first plane using the first regulating voltage; and a second peripheral circuit suitable for operating the second plane using the second regulating voltage, wherein the first regulator further provides a first reference voltage to the second regulator, and wherein the second regulator generates the second regulating voltage based on the first reference voltage.

### CROSS-REFERENCE TO RELATED APPLICATION

The present application claims priority to Korean patent application number 10-2015-0154518 filed on Nov. 4, 2015, in the Korean Intellectual Property Office, the entire disclosure of which incorporated herein in its entirety by reference.

### BACKGROUND

Field of Invention

Various embodiments of the present disclosure relate to a semiconductor electronic device, and more particularly, to a semiconductor memory device including a plurality of planes.

Description of Related Art

Semiconductor memory devices are memory devices embodied using a semiconductor such as silicon (Si), germanium (Ge), gallium arsenide (GaAs), Indium phosphide (InP), or the like. Semiconductor memory devices are classified into volatile memory devices and nonvolatile memory devices.

The volatile memory device is a memory device in which data stored therein is removed when power is turned off. Representative examples of the volatile memory device include static RAM (SRAM), dynamic RAM (DRAM), synchronous DRAM (SDRAM), and the like. The nonvolatile memory device is a memory device in which data stored therein is maintained even when power is turned off. Representative examples of a nonvolatile memory device include read only memory (ROM), programmable ROM (PROM), electrically programmable ROM (EPROM), electrically erasable programmable ROM (EEPROM), flash memory, phase-change random access memory (PRAM), magnetic RAM (MRAM), resistive RAM (PRAM) ferroelectric RAM (FRAM), and the like. Flash memory is classified into NOR type and NAND type memory.

### SUMMARY

Various embodiments of the present disclosure are directed to a semiconductor device having enhanced reliability.

One embodiment of the present disclosure provides a semiconductor device including: first and second regulators suitable for respectively generating first and second regulating voltages; first and second planes; a first peripheral circuit suitable for operating the first plane using the first regulating voltage; and a second peripheral circuit suitable for operating the second plane using the second regulating voltage, wherein the first regulator further provides a first reference voltage to the second regulator, and wherein the second regulator generates the second regulating voltage based on the first reference voltage.

The second regulator may include a comparator suitable for outputting the second regulating voltage by comparing a divided voltage of the second regulating voltage with the first reference voltage.

The first peripheral circuit may include: a first voltage domain suitable for operating the first plane using a first plane voltage; and a second voltage domain suitable for operating the first plane using the first regulating voltage.

The first regulator may generate the first reference voltage based on the first plane voltage.

Another embodiment of the present disclosure provides a semiconductor device including: a first semiconductor unit comprising: a first plane; a first regulator suitable for generating a first regulating voltage; and a first peripheral circuit suitable for operating using a first plane voltage and the first regulating voltage; and a second semiconductor unit comprising: a second plane; a second regulator suitable for generating a second regulating voltage; and a second peripheral circuit suitable for operating using a second plane voltage and the second regulating voltage, wherein the second regulator generates the second regulating voltage based on a first reference voltage provided from the first regulator, and wherein the first regulator generates the first regulating voltage based on a second reference voltage provided from the second regulator.

The first regulator may include a first reference voltage generation unit suitable for generating the first reference voltage based on the first plane voltage.

The second regulator may include a first comparator suitable for outputting the second regulating voltage by comparing a divided voltage of the second regulating voltage with the first reference voltage.

The second regulator may further include a second reference voltage generation unit suitable for generating the second reference voltage based on the second plane voltage.

The first regulator may further include a second comparator suitable for outputting the first regulating voltage by comparing a divided voltage of the first regulating voltage with the second reference voltage.

Yet another embodiment of the present disclosure provides a semiconductor device may include a plurality of semiconductor units, wherein a first one among the semiconductor units provides a first reference voltage to a second one among the semiconductor units, wherein the first semiconductor unit generates a regulating voltage based on a second reference voltage provided from a third one among the semiconductor units, and wherein each of the semiconductor units comprising: a plane; a regulator suitable for generating the regulating voltage based on one of the first and second reference voltages, and generating the other one of the first and second reference voltages based on a plane voltage; and voltage domains suitable for operating the plane using the plane voltage and the regulating voltage.

The second semiconductor unit may be the third semiconductor unit.

The plane voltages of the semiconductor units may be different from one another.

The present disclosure provides a semiconductor device having enhanced reliability.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the invention to those skilled in the relevant art.

In the drawings, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a semiconductor device according to an embodiment of the present disclosure;

FIG. 2 is a block diagram illustrating in more detail the semiconductor device of FIG. 1;

FIG. 3 is a block diagram illustrating in more detail a first semiconductor unit of FIG. 2;

FIG. 4 is a block diagram illustrating in more detail a second semiconductor unit of FIG. 2;

FIG. 5 is a view illustrating in more detail first and second reference voltage generation units and first and second regulating units of FIGS. 3 and 4;

FIG. 6 is a block diagram showing a memory system including the semiconductor device of FIG. 1;

FIG. 7 is a block diagram showing an example of application of the memory system of FIG. 6; and

FIG. 8 is a block diagram showing a computing system including the memory system illustrated with reference to FIG. 7.

### DETAILED DESCRIPTION

Hereinafter, an exemplary embodiment of the present disclosure will be described in detail with reference to the attached drawings. Ire the following description, only parts required for understanding of operations in accordance with the present disclosure will be described, and explanation of the other parts will be omitted not to make the gist of the present disclosure unclear. Accordingly, the present disclosure is not limited to the following embodiment but may be embodied in other types. Rather, this embodiment is provided so that the present disclosure will be thorough, and complete, and will fully convey the technical spirit of the disclosure to those skilled in the art.

It is also noted that in this specification, “connected/coupled” refers to one component not only directly coupling another component but also indirectly coupling another component through an intermediate component. On the other hand, “directly connected/directly coupled” refers to one component directly coupling another component without an intermediate component.

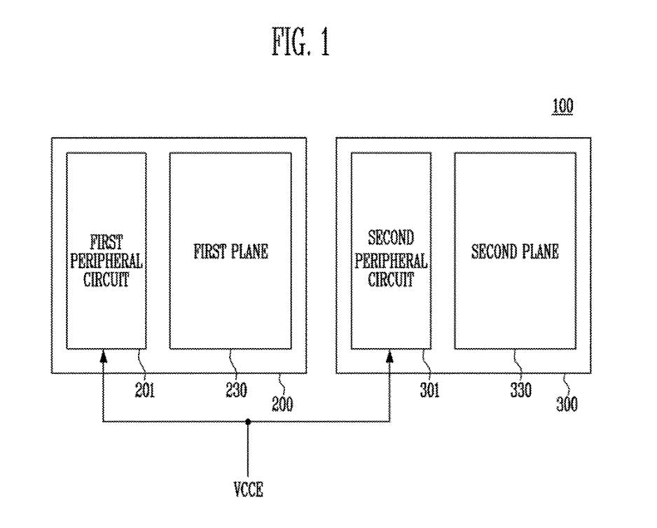

FIG. 1 is a block diagram illustrating a semiconductor device 100 according to an embodiment of the present disclosure.

Referring to FIG. 1, the semiconductor device 100 may include a plurality of semiconductor units 200 and 300. In FIG. 1, the semiconductor device 100 is illustrated as including two semiconductor units 200 and 300. However, this is only for illustrative purposes, and it will be understood that the semiconductor device 100 may include more than two semiconductor units.

The first and second semiconductor units 200 and 300 may operate using an externally provided external power voltage VCCE. In an embodiment, each of the first and second semiconductor units 200 and 300 may generate an internal operating voltage by regulating the external power voltage VCCE. Each of the first and second semiconductor units 200 and 300 may also operate using the internal operating voltage.

The first semiconductor unit 200 may include a first peripheral circuit 201 and a first plane 230. The first peripheral circuit 201 may control the first plane 230. The first plane 230 may include a plurality of memory cells. The first peripheral circuit 201 may program data to the memory cells, read data from the memory cells, or erase the data stored in the memory cells.

The second semiconductor unit 300 may be configured in the same manner as that of the first semiconductor unit 200. The second semiconductor unit 300 may include a second peripheral circuit 301 and a second plane 330. The second plane 330 may include a plurality of memory cells. The second peripheral circuit 301 may program data to the memory cells, read data from the memory cells, or erase the data stored in the memory cells.

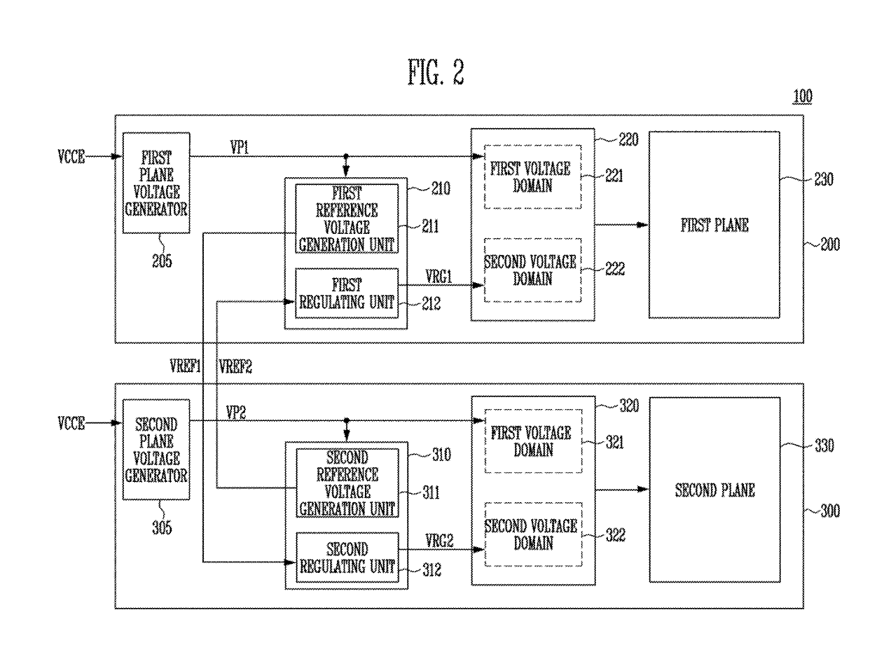

FIG. 2 is a block diagram illustrating in more detail the semiconductor device of FIG. 1.

Referring to FIG. 2, the semiconductor device 100 may include the semiconductor units 200 and 300.

The first semiconductor unit 200 may include a first plane voltage generator 205, a first regulator 210, the first: peripheral circuit 220, and the first plane 230.

The first plane voltage generator 205 may receive the external power voltage VCCE. The first plane voltage generator 205 may generate a first plane voltage VP1 by regulating the provided external power voltage VCCE. The first plane voltage VP1 may be used as an internal operating voltage for the first semiconductor unit 200. The first plane voltage VP1 may be provided to the first peripheral circuit 220 and the first regulator 210.

In another embodiment the external power voltage VCCE may be provided to the first peripheral circuit 220 and the first regulator 210 as the first plane voltage VP1.

The first regulator 210 may receive the first plane voltage VP1. The first regulator 210 may include a first reference voltage generation unit 211 and a first regulating unit 212. The first reference voltage generation unit 211 may regulate the first plane voltage VP1 and generate the first reference voltage VREF1. The first reference voltage VREF1 may differ from the first plane voltage VP1. The first reference voltage VREF1 may be provided to the second semiconductor unit 300.

The first regulating unit 212 may receive a second reference voltage VREF2 from the second semiconductor unit 300. The first regulating unit 212 may generate a first regulating voltage VRG1 based on the second reference voltage VREF2. The first regulating voltage VRG1 may differ from the first plane voltage VP1. In an embodiment, the first regulating unit 212 may include a comparator which compares a divided voltage of the first regulating voltage VRG1 with the second reference voltage VREF2. The first regulating unit 212 may output a predetermined level of the first regulating voltage VRG1 depending on the result of the comparison.

The first peripheral circuit 220 may include a first voltage domain 221 and a second voltage domain 222. The first voltage domain 221 may use the first plane voltage VP1 as an operating voltage and control the first plane 230. The second voltage domain 222 may use the first regulating voltage VRG1 as an operating voltage and control the first plane 230. Although not shown in FIG. 2, the second voltage domain 222 may use at least one of the first regulating voltage VRG1 and the first plane voltage VP1 as an operating voltage.

The second semiconductor unit 300 may include a second plane voltage generator 305, a second regulator 310, the second peripheral circuit 320, and the second plane 330.

The second plane voltage generator 305 may generate a second plane voltage VP2 by regulating the provided external power voltage VCCE. The second plane voltage VP2 may be used as an internal operating voltage for the second semiconductor unit 300. The second plane voltage VP2 may be provided to the second peripheral circuit 320 and the second regulator 310.

It will be understood that, as another embodiment, the external power voltage VCCE may be provided to the second peripheral circuit 320 and the second regulator 310 as the second plane voltage VP2.

The second regulator 310 may receive the second plane voltage VP2. The second regulator 310 may include a second reference voltage generation unit 311 and a second regulating unit 312. The second reference voltage generation unit 311 may regulate the second plane voltage VP2 and generate the second reference voltage VREF2 different from the second plane voltage VP2. The generated second reference voltage VREF2 may be provided to the first semiconductor unit 200.

The second regulating unit 312 may generate a second regulating voltage VRG2 based on the first reference voltage VREF1 provided from the first semiconductor unit 200. The second regulating voltage VRG2 may differ from the second plane voltage VP2.

That is, the first semiconductor unit 200 may generate the first regulating voltage VRG1 using the second reference voltage VREF2 generated from the second semiconductor unit 300 in lieu of using the first reference voltage VREF1 generated therefrom. The second semiconductor unit 300 may generate the second regulating voltage VRG2 using the first reference voltage VREF1 generated from the first semiconductor unit 200 in lieu of using the second reference voltage VREF2 generated therefrom. Having this ability to cross use the first and second reference voltages is advantageous as it will be explained below.

The second peripheral circuit 320 may include a first voltage domain 321 and a second voltage domain 322. The first voltage domain 321 may use the second plane voltage VP2 as an operating voltage and control the second plane 330. The second voltage domain 322 may use the second regulating voltage VRG2 as an operating voltage and control the second plane 330. In an embodiment, the second voltage domain 322 may be operated using at least one of the second plane voltage VP2 and the second regulating voltage VRG2 as an operating voltage.

It may be assumed that the first plane 230 is selected. In this case, the first peripheral circuit 220 may access the first plane 230. The first peripheral circuit 220 may access the first plane 230 using the first plane voltage VP1 and or the first regulating voltage VRG1. The first peripheral circuit 220 may consume a relatively large amount of current. Thereby, the first plane voltage VP1 may swing. Since the first reference voltage VREF1 is generated on the basis of the first plane voltage VP1 the level thereof may be unstable. When the first regulating unit 212 performs a regulating operation based on the first reference voltage VREF1, the first regulating voltage VRG1 may excessively swing. When the first regulating voltage VRG1 swings, the operation reliability of the second voltage domain 222 may deteriorate. When the allowable error range of the first regulating voltage VRG1 is comparatively small, or it is required that the level of the first regulating voltage VRG1 is comparatively accurate, the reliability of the second voltage domain 222 may further deteriorate.

In accordance with an embodiment of the present disclosure, the first regulating unit 212 may perform regulating operation based on the reference voltage VREF2 generated from the second semiconductor unit 300. The first regulating unit 212 may generate a regulating voltage VRG1 having a more stable level. Therefore, the reliability of the operation of the second voltage domain 222 may be enhanced.

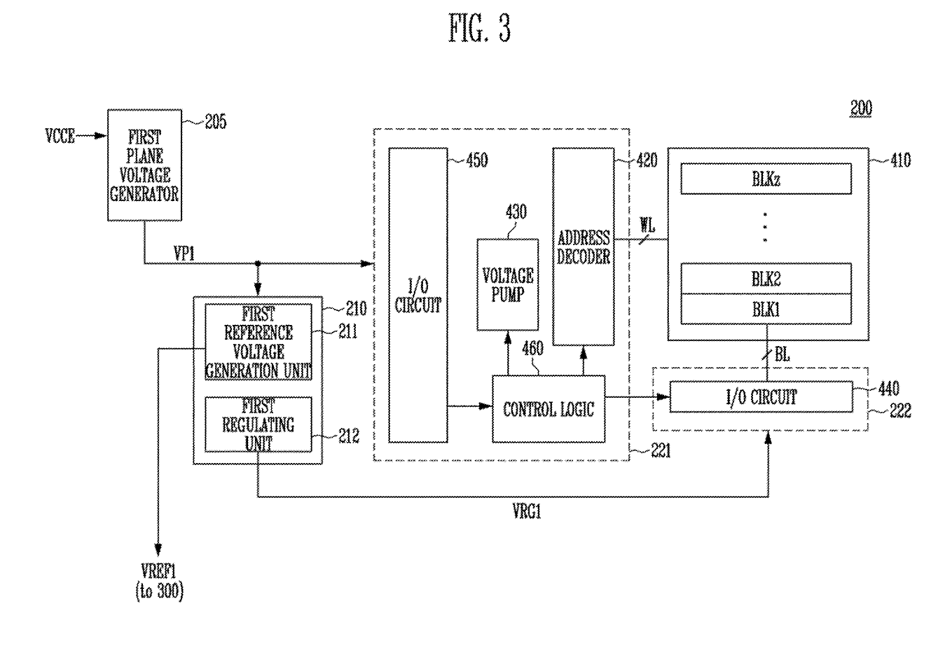

FIG. 3 is a block diagram illustrating in more detail the first semiconductor unit 200.

Referring to FIG. 3, the first semiconductor unit 200 may include the first plane voltage generator 205, the first regulator 210, a memory cell array 410, an address decoder 420, a voltage pump 430, a read/write circuit 440, an input/output circuit 450, and a control logic 460.

The first plane 230 described with reference to FIG. 2 may be provided as the memory cell array 410. The memory cell array 410 may be coupled to the address decoder 420 through word lines WL. The memory cell array 410 may be coupled to the read/write circuit 440 through bit lines BL.

The memory cell array 410 may include a plurality of memory blocks BLK1 to BLKz. Each of the plurality of memory blocks may include a plurality of pages. In an embodiment, an erase operation of the first semiconductor unit 200 may be performed in units of memory blocks. A program operation and a read operation of the first semiconductor unit 200 may be performed in units of pages.

Each of the plurality of pages may include a plurality of memory cells. In an embodiment, the memory cells may be nonvolatile memory cells.

The address decoder 420 may be coupled to the memory cell array 410 through the word lines WL. The address decoder 420 may control the word lines WL under the control of the control logic 460. The address decoder 420 may receive addresses ADDR through the control logic 460.

The address decoder 420 may decode a block address among the addresses. The address decoder 420 may select one memory block corresponding to the decoded block address. The address decoder 420 may decode a row address among the addresses. The address decoder 420 may select a corresponding one of the word lines of the selected memory block in accordance with the decoded row address. Thereby, one page may be selected.

The address decoder 420 may be any suitable decoder and may include a plurality of circuits as may be needed. In an embodiment, the address decoder 420 may include a block decoder, a row decoder, and an address buffer. Other circuits may also be included.

The voltage pump 430 may be operated under the control of the control logic 460. The voltage pump 430 may generate a plurality of voltages us ing at least one of the first plane voltage VP1 and the external power voltage VCCE. In an embodiment, the voltage pump 430 may include a plurality of pumping capacitors that receive the first plane voltage, and generate a plurality of voltages by selectively activating the plurality of pumping capacitors under the control of the control logic 460. For example, the voltage pump 430 may generate a variety of voltages to be applied to the word lines WL and provide the generated voltages to the address decoder 420. The address decoder 420 may bias the provided voltages to the word lines WL in accordance to an address.

The read/write circuit 440 may be coupled to the memory cell array 410 through the bit lines BL. The read/write circuit 440 may be operated under the control of the control logic 460.

The read/write circuit 440 may receive the first regulating voltage VRG1 from the first regulating unit 212. The read/write circuit 440 may control voltages of the bit lines BL using the first regulating voltage VRG1 and perform an internal operation.

During a program operation, the read/write circuit 440 may control the bit lines BL in accordance with data to be programmed. Thereby, a selected page may be programmed. During a read operation, the read/write circuit 440 may control the bit lines BL and read data from the selected page through the bit lines BL. During an erase operation, the read/write circuit 440 may float the bit lines BL.

In an embodiment, the read/write circuit 440 may include page buffers (or page resistors).

The input/output circuit 450 may provide a command and an address, received from the outside, to the control logic 460. The input/output circuit 450 may transmit data, received from the outside, to the read/write circuit 440 during a program operation, and may output data, received from the read/write circuit 440, to the outside during a read operation.

The control logic 460 may control the first plane voltage generator 205, the first regulator 210, the address decoder 420, the voltage pump 430, the read/write circuit 440, and the input/output circuit 450. The control logic 460 may receive a command and an address from the input/output circuit 450. The control logic 460 may control the overall operation of the first semiconductor device 200 in response to the command. The control logic 460 may transmit the address to the address decoder 420.

In an embodiment, the first semiconductor unit 200 may be a flash memory device.

The first plane voltage generator 205 may generate the first plane voltage VP1 using the external power voltage VCCE. The first plane voltage VP1 may be provided to the first peripheral circuit 221 and the first regulator 210.

The first regulating unit 212 of the first regulator 210 may generate the first regulating voltage VRG1. The first regulating voltage VRG1 may be provided to the second voltage domain 222.

As illustrated in FIG. 3, the address decoder 420, the voltage pump 430, the input/output circuit 450, and the control logic 460 may be included in the first voltage domain 221 and use the first plane voltage VP1 as an operating voltage. The read/write circuit 440 may be included in the second voltage domain 222 and use the first regulating voltage VRG1 as an operating voltage. The read and write circuit 440 may be operated using at least one of the first regulating voltage VRG1 and the first plane voltage VP1.

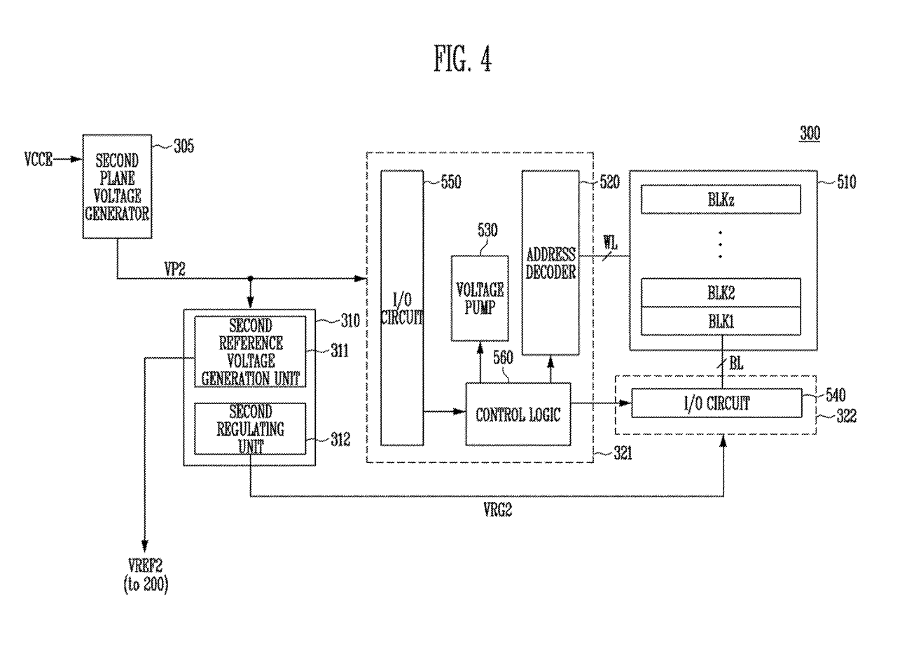

FIG. 4 is a block diagram illustrating in more detail the second semiconductor unit 300.

Referring to FIG. 4, the second semiconductor unit 300 may be configured in the same manner as that of the first semiconductor unit 200. The first semiconductor unit 300 may include the second plane voltage generator 305, the second regulator 310, a memory cell array 510, an address decoder 520, a voltage pump 530, a read/write circuit 540, an input/output circuit 550, and a control logic 560. The second plane 330 described with reference to FIG. 2 may be provided as the memory cell array 510.

The second plane voltage generator 305 may generate the second plane voltage VP2 using the external power voltage VCCE. The second plane voltage VP2 may be provided to the first voltage domain 321 and the second regulator 310.

The second regulating unit 312 of the second regulator 310 may generate the second regulating voltage VRG2. The second regulating voltage VRG2 may be provided to the second voltage domain 322.

As illustrated in FIG. 4, the address decoder 520, the voltage pump 530, the input/output circuit 550, and the control logic 560 may be included in the first voltage domain 321 and use the second plane voltage VP2 as an operating voltage. The read/write circuit 540 may be included in the second voltage domain 322 and use the second regulating voltage VRG2 as an operating voltage. In an embodiment, the read/write circuit 540 may be operated using at least one of the second regulating voltage VRG2 and the second plane voltage VP2.

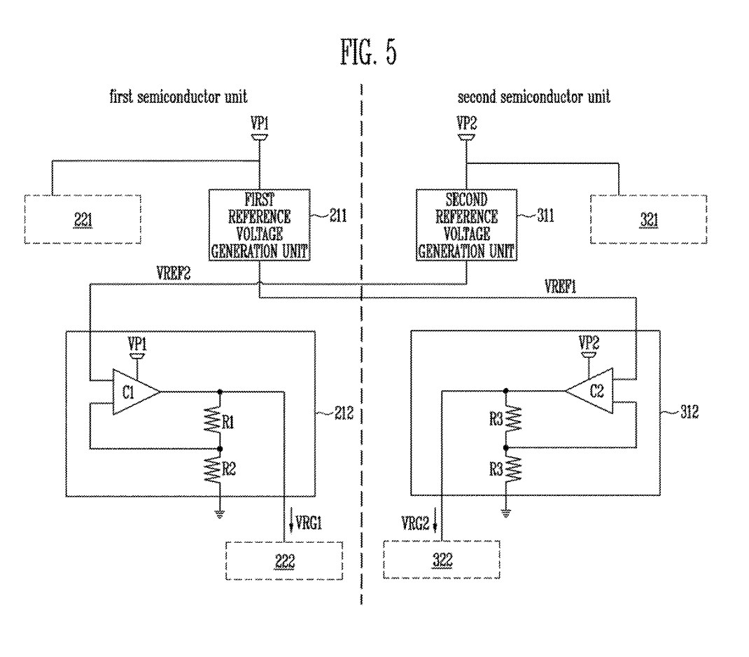

FIG. 5 is a view illustrating in more detail the first and second reference voltage generation units 211 and 311 and the first and second regulating units 212 and 312.

Referring to FIG. 5, the first plane voltage VP1 may be provided to the first reference voltage generation unit 211 and the first voltage domain 221 in the first semiconductor unit 200. The second plane voltage VP2 may be provided to the second reference voltage generation unit 311 and the first voltage domain 321 in the second semiconductor unit 300.

The second reference voltage generation unit 311 may generate the second reference voltage VREF2 by regulating the second plane voltage VP2. As described above, the second reference voltage VREF2 may be provided to the first regulating unit 212 rather than to the second regulating unit 312.

The first regulating unit 212 may generate the first regulating voltage VRG1 based on the second reference voltage VREF2. The first regulating unit 212 may include a first comparator C1 and first and second resistance elements R1 and R2. The first comparator C1 may compare a divided voltage of the first regulating voltage VRG1 with the second reference voltage VREF2 and output the first regulating voltage VRG1.

In more detail, a first input terminal of the first comparator C1 may receive the second reference voltage VREF2. A second input terminal of the first comparator C1 may be coupled to a node between the first and second resistance elements R1 and R2. The first plane voltage VP1 may be provided as an operating voltage of the first comparator C1. The first and second resistance elements R1 and R2 may be coupled in series between an output node of the first comparator C1 and a ground. The divided voltage of the first regulating voltage VRG1 may be formed from the node between the first and second resistance elements R1 and R2. The divided voltage of the first regulating voltage VRG1 may be provided to the second input terminal of the first comparator C1. The first comparator C1 may compare the divided voltage of the second input terminal with the second reference voltage VREF2 of the first input terminal and output the first regulating voltage VRG1 depending on the result of the comparison.

The first regulating voltage VRG1 may be provided to the second voltage domain 222 of the first semiconductor unit 200.

The first reference voltage generation unit 211 may generate the first reference voltage VREF1 by regulating the first plane voltage VP1. As described above, the first reference voltage VREF1 may be provided to the second regulating unit 312 rather than to the first regulating unit 212.

The second regulating unit 312 may generate the second regulating voltage VRG2 based on the first reference voltage VREF1. The second regulating unit 312 may include a second comparator C2 and third and fourth resistance elements R3 and R4. The second comparator C2 may compare a divided voltage of the second regulating voltage VRG2 with the first reference voltage VREF1 and output the second regulating voltage VRG2.

A first input terminal of the second comparator C2 may receive the first reference voltage VREF1. A second input terminal of the second comparator C2 may be coupled to a node between the third and fourth resistance elements R3 and R4. The second plane voltage VP2 may be provided as an operating voltage of the second comparator C. The third and fourth resistance elements R3 and R4 may be coupled in series between an output node of the second comparator C2 and the ground. The divided voltage of the second regulating voltage VRG2 may be formed from the node between the third and fourth resistance elements R3 and R4. The second comparator C2 may compare the divided voltage of the second input terminal with the first reference voltage VREF1 of the first input terminal and output the second regulating voltage VRG2 depending on the result of the comparison.

The second regulating voltage VRG2 may be provided to second voltage domain 322 of the second semiconductor unit 300.

In accordance with the embodiment of the present disclosure, each semiconductor unit may receive a reference voltage generated based on a voltage in the other semiconductor unit and generate a regulating voltage based on the received reference voltage. The regulating voltage can be stably maintained. Therefore, the reliability of the semiconductor device can be enhanced.

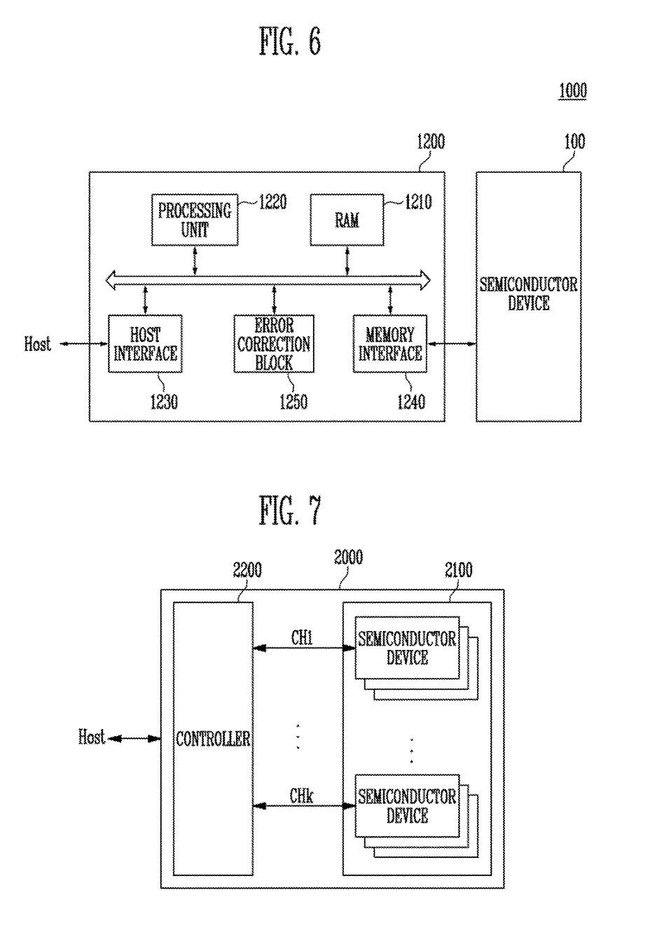

FIG. 6 is a block diagram illustrating a memory system 1000 including the semiconductor device 100 of FIG. 1, according to an embodiment of the invention.

Referring FIG. 6, the memory system 1000 may include the semiconductor device 100 and a controller 1200.

The semiconductor device 100 of FIG. 1 may be provided as a memory device. In this case the semiconductor device 100 may be coupled to the controller 1200. The semiconductor device 100 and the controller 1200 may form the single memory system 1000.

The controller 1200 may be coupled to a host and the semiconductor device 100. In response to a request from the host, the controller 1200 may access the semiconductor device 100. For example, the controller 1200 may control read, write, erase, and background operations of the semiconductor device 100. The controller 1200 may provide an interface between the host and the semiconductor device 100. The controller 1200 may drive firmware for controlling the semiconductor device 100.

The controller 1200 may include a RAM (random access memory) 1210, a processing unit 1220, a host interface 1230, a memory interface 1240, and an error correction block 1250.

The RAM 1210 may be used as at lease one of an operation memory of the processing unit 1220, a cache memory between the semiconductor device 100 and the host, and a buffer memory between the semiconductor device 100 and the host.

The processing unit 1220 may control the overall operation of the controller 1200.

The host interface 1230 may include a protocol for performing data exchange between the host and the controller 1200. In an exemplary embodiment, the controller 1200 may communicate with the host through at least one of various interface protocols such as a universal serial bus (USB) protocol, a multimedia card (MMC) protocol, a peripheral component interconnection (PCI) protocol, a PCI-express (PCI-E) protocol an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol, a private protocol, and the like.

The memory interface 1240 may interface with the semiconductor device 100. For example, the memory interface may include a NAND interface or a NOR interface.

The error correction block 1250 may use an error correction code (ECC) to detect and correct an error in data received from the semiconductor device 100.

The controller 1200 and the semiconductor device 100 may be integrated into a single semiconductor device. In an embodiment, the controller 1200 and the semiconductor device 100 may be integrated into a single semiconductor device to form a memory card. For example, the controller 1200 and the semiconductor device 100 may be integrated into a single semiconductor device and form a memory card, such as a personal computer memory card international association (PCMCIA), a compact flash card (CF), a smart media card (SM or SMC), a memory stick multimedia card (MMC, RS-MMC, or MMCmicro) a SD card (SD, miniSD, microSD, or SDRC), a universal flash storage (UFS) and the like.

The controller 1200 and the semiconductor device 100 may be integrated into a single semiconductor device to form a solid state drive (SSD). The SSD may include a storage device formed to store data in semiconductor memory. When the memory system 1000 is used as the SSD, an operation speed of the host coupled to the memory system 1000 may be substantially improved.

In another embodiment, the memory system 1000 may be provided as one of various elements of an electronic device, such as a computer, a ultra mobile PC (UMPC), a workstation, a net-book, a personal digital assistants (PDA), a portable computer, a web tablet, a wireless phone, a mobile phone, a smart phone, an e-book, a portable multimedia player (PMP), a game console, a navigation device, a black box a digital camera, a 3-dimensional television a digital audio recorder, a digital audio player, a digital picture recorder, a digital picture player, a digital video recorder, a digital video player, a device capable of transmitting/receiving information in an wireless environment, one of various devices for forming a home network one of various electronic devices for forming a computer network, one of various electronic devices for forming a telematics network an RFID device, one of various elements for forming a computing system, and the like.

As an embodiment, the semiconductor device 100 or the memory system 1000 may be embedded in various types of packages. For example, the semiconductor device 100 or the memory system 1000 may be packaged in a type such as Package on Package (PoP), Ball grid arrays (BGAs), Chip scale packages (CSPs), Plastic Leaded Chip Carrier (PLCO), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flatpack (TQFP), Small Outline (SOIC), Shrink Small Outline Package (SSOP) Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP) and the like.

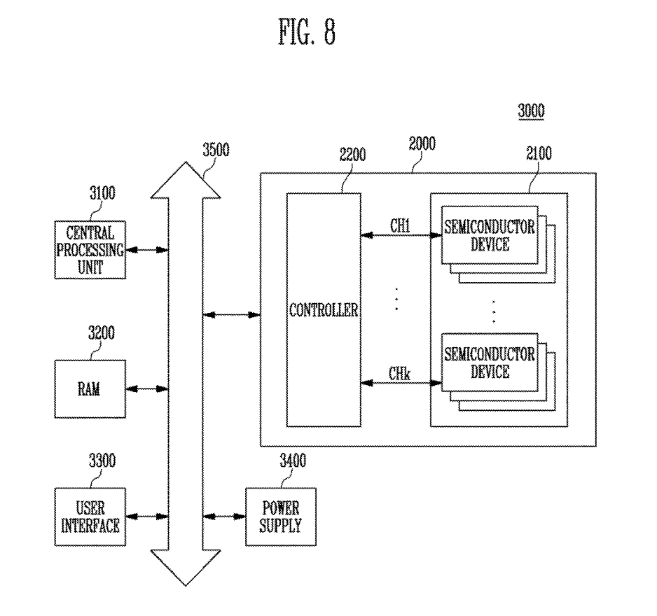

FIG. 7 is a block diagram showing an application example 2000 of the memory system 1000 of FIG. 6.

Referring FIG. 7, the memory system 2000 may include semiconductor devices 2100 and a controller 2200. The semiconductor devices 2100 may be divided into a plurality of groups.

In FIG. 7, it is illustrated that each of the plurality of groups communicates with the controller 2200 through first to k-th channels CH1 to CHk. Each semiconductor device may be configured and operated in the same manner as that of an embodiment of the semiconductor device 100 described with reference to FIG. 1.

Each group may communicate with the controller 2200 through a single common channel. The controller 2200 may have the same configuration as that of the controller 1200 described with reference to FIG. 6 and control the semiconductor devices 2100 through the channels CH1 to CHk.

In FIG. 7, a plurality of semiconductor devices are illustrated as being coupled to each channel. However, it will be understood that the memory system 2000 may be modified such that each semiconductor device is coupled to a single channel.

FIG. 8 is a block diagram illustrating a computing system 3000 including the memory system 2000 explained in relation to FIG. 7.

Referring to FIG. 8, the computing system 3000 may include a central processing unit 3100, a RAM 3200, a user interface 3300, power supply 3400, a system bus 3500, and a memory system 2000.

The memory system 2000 may be electrically coupled to the CPU 3100, the RAM 3200, the user interface 3300, and the power supply 3400 through the system bus 3500. Data provided through the user interface 3300 or processed by the CPU 3100 may be stored in the memory system 2000.

In FIG. 8 the semiconductor devices 2100 are illustrated as being coupled to the system bus 3500 through the controller 2200. However, the semiconductor devices 2100 may be directly coupled to the system bus 3500. The function of the controller 2200 may be performed by the CPU 3100 and the RAM 3200.

In FIG. 8, the case is illustrated in which the memory system 2000 described with reference to FIG. 7 is used. However, the memory system 2000 may be replaced with the memory system 1000 described with reference to FIG. 6. In an embodiment, the computing system 3000 may include both the memory systems 1000 and 2000 described with reference to FIGS. 6 and 7.

In accordance with an embodiment of the present disclosure, a regulating voltage of each semiconductor unit may be generated based on a reference voltage received from the other semiconductor unit. The regulating voltage can be stably maintained. Therefore, the reliability of the semiconductor device can be enhanced.

While the exemplary embodiments of the present disclosure have been disclosed for illustrative purposes, those skilled in the art will appreciate that various modifications, additions and substitutions are possible. Therefore, the scope of the present disclosure must be defined by the appended claims and equivalents of the claims rather than by the description preceding them.

1. A semiconductor device comprising:
first and second regulators suitable for respectively generating first and second regulated voltages;
first and second planes;
a first peripheral circuit suitable for operating the first plane using the first regulated voltage; and
a second peripheral circuit suitable for operating the second plane using the second regulated voltage,
wherein the first regulator, the first plane and the first peripheral circuit are included in a first semiconductor unit, and the second regulator, the second plane and the second peripheral circuit are included in a second semiconductor unit, and
wherein the first regulator further provides a first reference voltage to the second regulator, and the second regulator included in the second semiconductor unit generates the second regulated voltage based on the first reference voltage provided from the first regulator included in the first semiconductor unit.

2. The semiconductor device according to claim 1, wherein the second regulator comprises a comparator suitable for outputting the second regulated voltage by comparing a divided voltage of the second regulated voltage with the first reference voltage.

3. The semiconductor device according to claim 1, wherein the first peripheral circuit comprises:
a first voltage domain suitable for operating the first plane using a first plane voltage; and
a second voltage domain suitable for operating the first plane using the first regulated voltage.

4. The semiconductor device according to claim 3, wherein the first regulator generates the first reference voltage based on the first plane voltage.

5. The semiconductor device according to claim 3, wherein the second voltage domain comprises a read/write circuit coupled to the first plane.

6. The semiconductor device according to claim 1,
wherein the second regulator further provides a second reference voltage to the first regulator, and
wherein the first regulator included in the first semiconductor unit generates the first regulated voltage based on the second reference voltage provided from the second regulator included in the second semiconductor unit.

7. The semiconductor device according to claim 6, wherein the first regulator comprises a comparator suitable for outputting the first regulated voltage by comparing a divided voltage of the first regulated voltage with the second reference voltage and generates the first regulated voltage.

8. The semiconductor device according to claim 6, wherein the second peripheral circuit comprises:
a first voltage domain suitable for operating the second plane using a second plane voltage; and
a second voltage domain suitable for operating the second plane using the second regulated voltage.

9. The semiconductor device according to claim 8, wherein the second regulator generates the second reference voltage based on the second plane voltage.

10. The semiconductor device according to claim 8, wherein the second voltage domain comprises a read/write circuit coupled to the second plane.

11. A semiconductor device comprising:
a first semiconductor unit comprising:
a first plane;
a first regulator suitable for generating a first regulated voltage; and
a first peripheral circuit suitable for operating using a first plane voltage and the first regulated voltage; and
a second semiconductor unit comprising:
a second plane;
a second regulator suitable for generating a second regulated voltage; and
a second peripheral circuit suitable for operating using a second plane voltage and the second regulated voltage,
wherein the second regulator generates the second regulated voltage based on a first reference voltage provided from the first regulator, and
wherein the first regulator generates the first regulated voltage based on a second reference voltage provided from the second regulator.

12. The semiconductor device according to claim 11, wherein the first regulator comprises a first reference voltage generation unit suitable for generating the first reference voltage based on the first plane voltage.

13. The semiconductor device according to claim 12, wherein the second regulator comprises a first comparator suitable for outputting the second regulated voltage by comparing a divided voltage of the second regulated voltage with the first reference voltage.

14. The semiconductor device according to claim 13, wherein the second regulator further comprises a second reference voltage generation unit suitable for generating the second reference voltage based on the second plane voltage.

15. The semiconductor device according to claim 14, wherein the first regulator further comprises a second comparator suitable for outputting the first regulated voltage by comparing a divided voltage of the first regulated voltage with the second reference voltage.

16. The semiconductor device according to claim 11, wherein the first peripheral circuit comprises:
a first voltage domain suitable for operating the first plane using the first plane voltage; and
a second voltage domain suitable for operating the first plane using the first regulated voltage.

17. The semiconductor device according to claim 16, wherein the second peripheral circuit comprises:
a third voltage domain suitable for operating the second plane using the second plane voltage; and
a fourth voltage domain suitable for operating the second plane using the second regulated voltage.

18. A semiconductor device comprising a plurality of semiconductor units,
wherein each of the semiconductor units comprising:
a plane;
a regulator suitable for generating a regulated voltage based on a reference voltage generated from another semiconductor unit, and generating another reference voltage to be used in another semiconductor unit based on a plane voltage; and
voltage domains suitable for operating the plane using the plane voltage and the regulated voltage.

19. The semiconductor device according to claim 18, wherein the semiconductor units have the same configuration with each other.

20. The semiconductor device according to claim 18, wherein the plane voltages of the semiconductor units are different from one another.
